(19) United States
(12) Patent Application Publication
(10) Pub. No.: US 2009/0293935 A1
(43) Pub. Date: Dec. 3, 2009

(54) SOLAR COLLECTOR CAPABLE OF RECEIVING LIGHT RAYS WITH DIFFERENT INCIDENT ANGLES

(75) Inventors: Chung-Pin Liao, Taichung (TW); Chang-Jiang Cheng, Taipei (TW); Hsien-Ming Chang, Yunlin County (TW)

Correspondence Address: PAI PATENT & TRADEMARK LAW FIRM, 1001 FOURTH AVENUE, SUITE 3200, SEATTLE, WA, 98154, US

(73) Assignee: NATIONAL FORMOSA UNIVERSITY, Yunlin County (TW)

(21) Appl. No.: 12/184,202

(22) Filed: Jul. 31, 2008

(30) Foreign Application Priority Data
May 28, 2008 (TW) 97119780

(51) Int. Cl. H01L 31/042

(52) U.S. Cl. 136/246

(57) ABSTRACT

A solar collector includes a base having an internal chamber therein, a plurality of openings, and low reflection materials at an inner periphery thereof, a lens unit for enabling the sun's rays to penetrate into the internal chamber through the openings, an optical transfer unit disposed in the internal chamber to receive the sun's rays and transform that into electric energy, and at least one heat transfer member mounted to the base to transfer heat energy transformed by the sun's rays that is received by the low reflection materials. Thus, the solar collector of the present invention is capable of receiving the sun's rays with different incident angles to transform the sun's rays into the electric energy and the heat energy.

### BACKGROUND OF THE INVENTION

1. Field of the Invention

The present invention relates generally to solar energy, and more specifically to a solar collector capable of receiving the sun's rays that has different incident angles.

2. Description of the Related Art

With the rise of the environmental consciousness, the up-surging in energy prices, and the depletion in energy resources, renewable energy technologies that are used to replace conventional energy are becoming mature gradually and used extensively.

The renewable energy technologies include wind power, solar power, biomass, etc., which effectively use natural resources, such as wind, sunlight, biological materials, etc. By taking the solar power as an example, the common application of the solar power is concentrating sunlight for heating or converting the sunlight into electricity.

The conventional solar cell is a semiconductor device that is made of single-crystal silicon or polycrystal silicon, or single-crystal gallium arsenide, capable of absorbing the sunlight to generate electrons and holes, thereby producing electricity.

However, the silicon-based solar cell has an efficiency below 15%, an inefficiency of 35-45% due to the issues of an unversatile band gap, the voltage factor and the curved factor, and an efficiency of 30% in converting into heat energy. Although a lot of improved solar cells are provided, such as the dye-sensitized solar cell and the tandem cell, for enhancing the efficiencies, the efficiencies can reach 20% at most. Further, the incident angle of the sunlight is continuously changing because of the moving sun track, such that the solar cells have to be set into different positions to receive the sunlight with different incident angles, resulting in complication and inconvenience of installation of the solar cells.

### SUMMARY OF THE INVENTION

The present invention has been accomplished in view of the above-noted circumstances. It is one objective of the present invention to provide a solar collector, which can receive the sun's rays at different angles and transform them into electric energy and heat energy, thereby providing better efficiency in energy transformation.

To achieve this objective of the present invention, the solar collector comprises a base, a lens unit, an optical transform unit, and at least one heat transfer member. The base has an internal chamber therein, at least one opening in communication with the internal chamber, and low reflectivity dark materials at an inner periphery thereof facing the internal chamber. The lens unit concentrates the light rays from the sun in such a way to guide them into the internal chamber through the opening. Once the light rays penetrate into the internal chamber, they are unescapable from the internal chamber. The optical transform unit has at least one optical transform member disposed in the internal chamber of the base to receive the incident light rays and transform that into electric energy. The heat transfer member is mounted to the base.

Accordingly, the light rays from the sun will hit the optical transform member through the lens unit such that the optical transform member can receive the light rays and transform the light rays into the electric energy, and then a part of light rays from the sun will hit the low reflectivity materials so as to be transformed into heat energy and transferred to the heat transfer member.

The scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become fully understood from the detailed description given herein below and the accompanying drawings which are given by way of illustration only, and thus are not limitative of the present invention, and wherein:

FIG. 1 is a perspective view of the solar collector according to a preferred embodiment of the present invention, and

FIG. 2 is a cutaway view of the solar collector according to the preferred embodiment of the present invention.

### DETAILED DESCRIPTION OF THE INVENTION

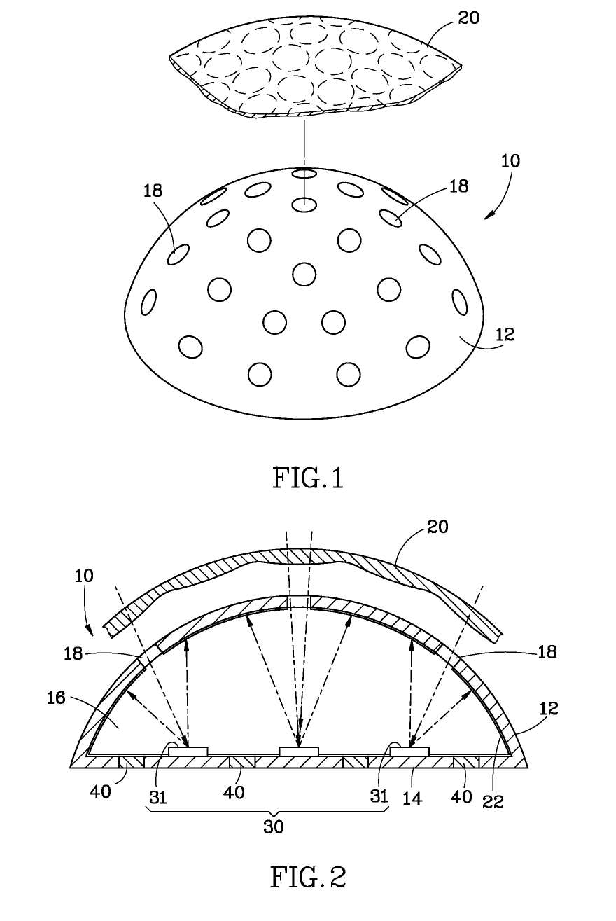

As shown in FIG. 1, a solar collector in accordance with a preferred embodiment of the present invention comprises a base 10, a lens unit 20. FIG. 2 further shows an optical transform unit 30, and a plurality of heat transfer members 40.

The base 10 has a curved top 12 and a bottom 14 connected to the top 12 so as to define an internal chamber 16 between the top 12 and the bottom 14. The top 12 has a plurality of openings 18 in communication with the internal chamber 16. Further, the base 10 is provided at inner peripheries of the top 12 and the bottom 14 with low reflectivity materials 22 that can receive the sun's rays and transform that into heat energy. The low reflectivity materials 22 are dark materials in this embodiment, having high imaginary parts of refractive index thereof and real parts of refractive index thereof nearly equal to one in a wavelength range between 250 nm and 300 nm of AM 1.5 solar spectrum, such as the widely used polypyrrole.

The lens unit 20 may have an arced shape, a flat shape, an arrayed shape, or other shapes. In this embodiment, as shown in FIG. 2, the lens unit 20 has an arced shape. Alternatively, the lens unit 20 can be formed of a plurality of wide-angle focusing lenses, each of which has a wide angle of view from 170 to 210 degrees, or a plurality of Fresnel lenses, which focus light rays by optical interference technology. The lens unit 20 can concentrate the light rays from the sun at different elevations to enable the sun's rays with different incident angles to penetrate into the internal chamber 16 through the openings 18.

The optical transform unit 30 includes a plurality of optical transform members 31, which are embodied as solar cells. The optical transform members 31 can be alternatively mounted on the inner peripheries of the top 12 and the bottom 14 of the base 10, or suspended in the internal chamber 16 of the base 10, such that the sun's rays penetrating into the internal chamber 16 through the lens unit 20 can be received by the optical transform members 31 and transformed into electric energy.

The heat transfer members 40 are mounted to the base 10 and located at a position where the heat transfer members 40 can receive the heat energy that is transformed by the sun's rays received by the low reflectivity materials 22. As shown in FIG. 2, the heat transfer members 40 are mounted to the bottom 14 of the base 10 and connected to the low reflectivity materials 22 so as to transfer the heat energy. The heat transfer members 40 can be fluids to transfer the heat energy to the outside of the base 10, or store the heat energy.

By means of the aforesaid design, when the sun's rays penetrate into the internal chamber 16 through the lens unit 20 and the openings 18 of the base 10, they can directly and alternately hit each of the optical transform members 31 such that the optical transform members 31 can transform a large part of the sun's rays into the electric energy. However, because the surfaces of the optical transform members 31 are different from perfect reflectors, a part of the sun's rays will simultaneously reflect off or scatter off the optical transform members 31 and arrive at the low reflectivity materials 22 when the sun's rays hit the optical transform members 31, such that the sun's rays can be transformed by the low reflectivity materials 22 into the heat energy, and then the heat energy can be transferred by the heat transfer members 40 to a required location.

As a result, when penetrating into the internal chamber 16 of the base 10, the sun's rays will be transformed by the optical transform members 31 into the electric energy, and the sun's rays that reflect off or scatter off the optical transform members 31 will be received by the low reflectivity materials 22 without leaving the internal chamber 16 through the openings 18, such that the sun's rays can be completely transformed into the electric energy and the heat energy. Further, if the solar collector of the present invention is used in a household power station or a hot water source, the base 10 can be designed into bigger dimensions for concentrating a great quantity of the sun's rays. Besides, the base 10 can also be designed into a small size to make the solar collector be a portable power package.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A solar collector comprising:
a base having an internal chamber therein, at least one opening in communication with said internal chamber, and low reflectivity materials at an inner periphery thereof facing said internal chamber;
a lens unit concentrating the light rays from the sun for enabling the light rays to penetrate into said internal chamber through said opening;
an optical transform unit having at least one optical transform member disposed in said internal chamber of said base to receive the light rays and transform that into electric energy; and
at least one heat transfer member mounted to said base;
whereby the light rays can hit said optical transform member through said lens unit such that said optical transform member can receive the light rays and transform that into the electric energy, and a part of the light rays can hit said low reflectivity materials to be transformed into heat energy and transferred to said heat transfer member.

2. The solar collector as claimed in claim 1, wherein said low reflectivity materials are dark materials.

3. The solar collector as claimed in claim 1, wherein said lens unit has a flat shape, an arced shaped, or an arrayed shape.

4. The solar collector as claimed in claim 1, wherein said lens unit includes a plurality of wide-angle focusing lenses.

5. The solar collector as claimed in claim 4, wherein said wide-angle focusing lenses each have a wide angle of view from 170 to 210 degrees.

6. The solar collector as claimed in claim 1, wherein said lens unit includes a plurality of Fresnel lenses.

7. The solar collector as claimed in claim 1, wherein said optical transform member is mounted on said inner periphery of said base that faces said internal chamber.

8. The solar collector as claimed in claim 1, wherein said optical transform member is suspended in said internal chamber of said base.

9. The solar collector as claimed in claim 1, wherein said heat transfer member is mounted to said base and connected to said low reflectivity materials for transferring the heat energy transformed by the light rays received by said low reflectivity materials.
